(19) United States
(12) Patent Application Publication
(10) Pub. No.: US 2024/0365478 A1
(43) Pub. Date: Oct. 31, 2024

(54) CIRCUIT BOARD, DISPLAY APPARATUS, AND MANUFACTURING METHOD FOR CIRCUIT BOARD

(71) Applicant: BOE Technology Group Co., Ltd., Beijing (CN)

(72) Inventors: Guoteng LI, Beijing (CN); Shuilang DONG, Beijing (CN); Xinhong LU, Beijing (CN); Liuqing LI, Beijing (CN); Jingshang ZHOU, Beijing (CN); Baoman LI, Beijing (CN); Zhao CUI, Beijing (CN); Yingwei LIU, Beijing (CN)

(21) Appl. No.: 18/769,438

(22) Filed: Jul. 11, 2024

Related U.S. Application Data
(63) Continuation of application No. PCT/CN2023/082846, filed on Mar. 21, 2023.

(51) Int. Cl. H05K 3/46; H05K 1/11; H05K 3/16; H05K 3/40; H05K 5/00

(52) U.S. Cl. CPC H05K 3/4691; H05K 1/111; H05K 3/16; H05K 3/4007; H05K 5/0069; H05K 2203/0143; H05K 2203/0723; H05K 2203/1377

(57) ABSTRACT

Embodiments of the present disclosure provide a circuit board, a display apparatus, and a manufacturing method for a circuit board. The manufacturing method for the circuit board includes: providing a precursor substrate; forming seed patterns and an auxiliary seed pattern on a side of the precursor substrate, where the seed patterns are located in the patterned areas, the auxiliary seed pattern is located in the non-patterned area, and the seed pattern and the auxiliary seed pattern are separated from each other; and forming a pad at a position of the seed pattern and an auxiliary pattern at a position of the auxiliary seed pattern by an electroplating process.

### CROSS REFERENCE TO RELATED APPLICATION

This application is a continuation application of International Application No. PCT/CN2023/082846, filed on Mar. 21, 2023, which is hereby incorporated by reference in its entirety.

### TECHNICAL FIELD

The present disclosure relates to the field of semiconductor technology, and in particular to a circuit board, a display apparatus, and a manufacturing method for a circuit board.

### BACKGROUND

At present, the development of three-dimensional (3D) display technology is fast, and intelligence and portability are the centralized development direction of current electronic products. The 3D display products require an increase in the quantity of data channels from 4k to 10k+, and at the same time have a series of new requirements for the driver chip (IC) packaging technology. The IC packaging technology with the high channel quantity that supports more functions has become a limiting factor for the development of future 3D display products. Therefore, it is necessary to develop the ultra-high-resolution chip on film (COF) to develop the IC packaging technology with the high channel quantity. Based on the structural characteristics of the COF, electroplating patterns are different at different bonding areas (e.g., the bonding area for bonding a display substrate (OLB Bonding), the bonding area for bonding a flexible circuit board (FOF Bonding), and the bonding area for bonding ICs (ILB Bonding)), and the electroplating uniformity is poor after the thick Cu is electroplated, which cannot meet the requirements of accuracy of the subsequent COF bonding process and the product yield.

### SUMMARY

Embodiments of the present disclosure provide a manufacturing method for a circuit board, where the circuit board has a plurality of patterned areas, and a non-patterned area outside the patterned areas. The manufacturing method includes: providing a precursor substrate; forming seed patterns and an auxiliary seed pattern on a side of the precursor substrate, where the seed patterns are located in the patterned areas, the auxiliary seed pattern is located in the non-patterned area, and the seed pattern and the auxiliary seed pattern are separated from each other; and forming a pad at a position of the seed pattern and an auxiliary pattern at a position of the auxiliary seed pattern by an electroplating process.

In a possible implementation, the forming the seed patterns and the auxiliary seed pattern on the side of the precursor substrate, includes: forming a plurality of the seed patterns in the patterned areas of the precursor substrate; forming an auxiliary film having the auxiliary seed pattern and a hollowed area, where the auxiliary seed pattern includes: a first flexible substrate, and a first auxiliary seed film layer on a side of the first flexible substrate; and attaching a side of the auxiliary film having the first flexible substrate to a side of the precursor substrate having the seed pattern, where the patterned area of the precursor substrate is attached to the hollowed area of the auxiliary film.

In a possible implementation, the forming the auxiliary film having the auxiliary seed pattern and the hollowed area, includes: providing a rigid substrate; forming the first flexible substrate and the first auxiliary seed film layer sequentially on a side of the rigid substrate; cutting the first flexible substrate and the first auxiliary seed film layer to remove an area without the auxiliary seed pattern to form the hollowed area; and removing the rigid substrate.

In a possible implementation, the attaching the side of the auxiliary film having the first flexible substrate to the side of the precursor substrate having the seed pattern, includes: attaching the side of the auxiliary film having the first flexible substrate to the side of the precursor substrate having the seed pattern by a roller rolling.

In a possible implementation, after forming the pad at the position of the seed pattern and the auxiliary pattern at the position of the auxiliary seed pattern by the electroplating process, the manufacturing method further includes: removing the auxiliary film.

In a possible implementation, after removing the auxiliary film, the manufacturing method further includes: forming a protective layer on a surface of the pad; and forming a solder resist layer in the non-patterned area.

In a possible implementation, the forming the seed patterns and the auxiliary seed pattern on the side of the precursor substrate, includes: forming a second seed film layer on the precursor substrate by a sputtering process; and forming a plurality of the seed patterns in the patterned areas, and forming the auxiliary seed pattern in the non-patterned area, by performing a patterning process on the second seed film layer, where a gap is provided between the auxiliary seed pattern and the seed pattern.

In a possible implementation, after forming the pad at the position of the seed pattern and the auxiliary pattern at the position of the auxiliary seed pattern by the electroplating process, the manufacturing method further includes: forming a protective layer on surfaces of the pad and the auxiliary pattern; and forming a solder resist layer in an area where the auxiliary pattern is located.

In a possible implementation, the providing the precursor substrate, includes: providing a base substrate; forming a plurality of leads on a side of the base substrate; and forming a planarization layer on a side of the leads facing away from the base substrate, where the planarization layer has via holes exposing portions of the leads.

Embodiments of the present disclosure further provide a circuit board, including: a base substrate, where the base substrate has patterned areas and a non-patterned area outside the patterned areas; a plurality of pads, located on a side of the base substrate and located in the patterned areas; and an auxiliary pattern, where the auxiliary pattern and the pads are on a same side of the base substrate, and the auxiliary pattern is in the non-patterned area.

In a possible implementation, a gap is provided between the auxiliary pattern and the pad.

In a possible implementation, the auxiliary pattern and the pads are on a same layer and have a same material.

In a possible implementation, a surface of the auxiliary pattern facing away from the base substrate is on a same plane as a surface of the pad facing away from the base substrate.

In a possible implementation, the circuit board further includes: a plurality of leads between the base substrate and the pads; a planarization layer, located between the plurality of leads and the pads, and having via holes exposing portions of the plurality of leads, where the plurality of leads are electrically connected with the pads in one-to-one correspondence through the via holes; a protective layer, located on a side of the pad facing away from the planarization layer and covering the pad and the auxiliary pattern; and a solder resist layer, located on a side of the auxiliary pattern facing away from the planarization layer and covering the auxiliary pattern.

Embodiments of the present disclosure further provide a display apparatus, including: a display panel; a flexible circuit board; a control chip; and a circuit board obtained by the manufacturing method according to embodiments of the present disclosure, or, a circuit board according to embodiments of the present disclosure. The plurality of patterned areas of the circuit board include: a first patterned area, a second patterned area, and a third patterned area; the display panel includes a plurality of first pins, and the plurality of first pins of the display panel are bonded one-to-one with pads in the first patterned area; the flexible circuit board includes a plurality of second pins, and the plurality of second pins of the flexible circuit board are bonded one-to-one with pads in the second patterned area; and the control chip has a plurality of third pins, and the plurality of third pins of the control chip are bonded one-to-one with pads in the third patterned area.

### BRIEF DESCRIPTION OF FIGURES

FIG. 1 shows a first schematic diagram of distribution of power lines of an electroplated sample.

FIG. 2 shows a second schematic diagram of distribution of power lines of an electroplated sample.

FIG. 3 shows a schematic diagram of a process for manufacturing a circuit board according to embodiments of the present disclosure.

FIG. 4A shows a schematic diagram of a precursor substrate with formed leads according to embodiments of the present disclosure.

FIG. 4B shows a schematic diagram of a top view of formed leads according to embodiments of the present disclosure.

FIG. 4C shows a schematic diagram of a precursor substrate with a formed planarization layer according to embodiments of the present disclosure.

FIG. 4D shows a schematic diagram of a precursor substrate with a formed insulating layer according to embodiments of the present disclosure.

FIG. 4E shows a schematic diagram of a precursor substrate with formed seed patterns according to embodiments of the present disclosure.

FIG. 5A shows a schematic diagram of a top view of first alignment marks when forming an auxiliary film according to embodiments of the present disclosure.

FIG. 5B shows a cross-sectional schematic diagram of first alignment marks when forming an auxiliary film according to embodiments of the present disclosure.

FIG. 5C shows a schematic diagram of a first seed film layer when forming an auxiliary film according to embodiments of the present disclosure.

FIG. 5D shows a schematic diagram of removing a periphery of first alignment marks when forming an auxiliary film according to embodiments of the present disclosure.

FIG. 5E shows a schematic diagram after removing a periphery of first alignment marks when forming an auxiliary film according to embodiments of the present disclosure.

FIG. 5F shows a schematic diagram of a motherboard including a plurality of COFs according to embodiments of the present disclosure.

FIG. 5G shows a schematic diagram of forming a hollowed area in an auxiliary film according to embodiments of the present disclosure.

FIG. 5H shows a schematic diagram of peeling an auxiliary film from a rigid substrate according to embodiments of the present disclosure.

FIG. 5I shows a schematic diagram of an obtained auxiliary film according to embodiments of the present disclosure.

FIG. 5J shows a schematic diagram of a top view of an auxiliary film corresponding to a single COF according to embodiments of the present disclosure.

FIG. 5K shows a cross-sectional schematic diagram of an auxiliary film corresponding to a single COF according to embodiments of the present disclosure.

FIG. 6A shows a schematic diagram of a top view of attaching an auxiliary film to a precursor substrate formed with seed patterns according to embodiments of the present disclosure.

FIG. 6B shows a cross-sectional schematic diagram of attaching an auxiliary film to a precursor substrate formed with seed patterns according to embodiments of the present disclosure.

FIG. 7 shows a first cross-sectional schematic diagram after electroplating pads according to embodiments of the present disclosure.

FIG. 8 shows a cross-sectional schematic diagram of a COF after removing an auxiliary film according to embodiments of the present disclosure.

FIG. 9 shows a cross-sectional schematic diagram of a COF with a formed protective layer and a formed solder resist layer according to embodiments of the present disclosure.

FIG. 10 shows a cross-sectional schematic diagram of forming seed patterns and an auxiliary seed pattern at the same time according to embodiments of the present disclosure.

FIG. 11 shows a cross-sectional schematic diagram of a COF with a formed protective layer and a formed solder resist layer according to embodiments of the present disclosure.

FIG. 12 shows a schematic diagram of a display apparatus according to embodiments of the present disclosure.

FIG. 13 shows a schematic diagram of connection between pads and leads according to embodiments of the present disclosure.

FIG. 14 shows a schematic diagram of comparison of uniformity with an auxiliary pattern and uniformity without an auxiliary pattern according to embodiments of the present disclosure.

### DETAILED DESCRIPTION

In order to make the objects, technical solutions and advantages of embodiments of the present disclosure clearer, the technical solutions of embodiments of the present disclosure will be described clearly and completely in the following in conjunction with the accompanying drawings of embodiments of the present disclosure. Obviously, the described embodiments are a part of embodiments of the present disclosure and not all of embodiments. Based on the described embodiments of the present disclosure, all other embodiments obtained by a person of ordinary skill in the art without creative labor fall within the protection scope of the present disclosure.

Unless otherwise defined, technical or scientific terms used in the present disclosure shall have the ordinary meaning understood by a person of ordinary skill in the field to which the present disclosure belongs. The words “first”, “second”, and the like used in the present disclosure do not indicate any order, number, or significance, but are only used to distinguish different components. The words “including” or “comprising” and the like are intended to mean that the component or object before the word encompasses the components or objects listed after the word and their equivalents, without excluding other components or objects. Words such as “connected” or “coupled” are not limited to physical or mechanical connections, but may include electrical connections, whether direct or indirect. The words “up”, “down”, “left”, “right” and the like are used only to indicate relative positional relationships. When the absolute position of the described object changes, the relative positional relationship may also change accordingly.

As used herein, “about” or “approximately the same” includes the stated value and means an acceptable range of deviation from the specific value determined by a person of ordinary skill in the art taking into account the measurements discussed and the errors associated with the measurement of the specific quantity (i.e., the limitations of the measurement system). For example, “substantially the same” may mean that the difference relative to the stated value is within one or more standard deviation ranges, or within ±30%, 20%, 10%, 5%.

In the accompanying drawings, the thicknesses of layers, films, panels, areas and the like are enlarged for clarity. Exemplary embodiments are described herein with reference to a cross-sectional view as a schematic diagram of an idealized implementation mode. In this way, deviations from the shape of the drawing as a result of, such as manufacturing techniques and/or tolerances, will be expected. Thus, the implementation modes described in the disclosure should not be construed as being limited to the specific shape of an area shown in the disclosure, but includes deviations in shape caused by, for example, manufacturing. For example, flat areas illustrated or described may typically have rough and/or non-linear features. Furthermore, the sharp corner illustrated may be rounded. Thus, the areas shown in the drawings are schematic in nature, and their shapes are not intended to illustrate the precise shapes of the areas and are not intended to limit the scope of the claims of the disclosure.

In order to keep the following description of embodiments of the present disclosure clear and concise, the present disclosure omits detailed descriptions of known functions and known components.

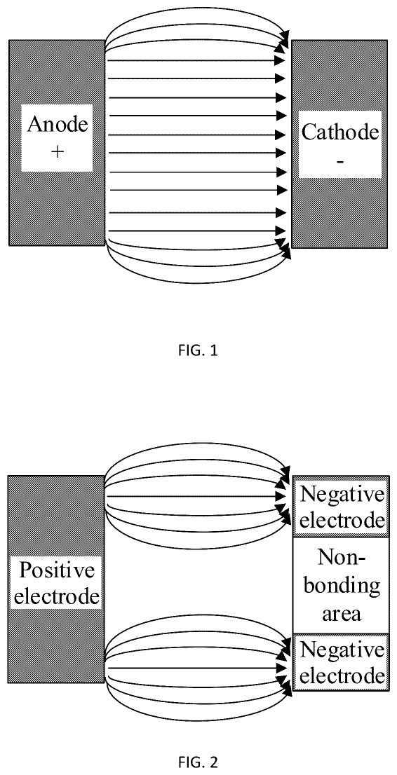

When electroplating the whole plate, a schematic diagram of distribution of power lines of an electroplated sample is shown in FIG. 1, the power lines are uniformly distributed from an anode to a cathode, and thicknesses of electroplated positions are uniform. When a patterned sample is electroplated with Cu, a schematic diagram of distribution of power lines thereof is shown in FIG. 2, and the power lines in part of the cathode area are too concentrated, which causes problems such as burrs in the electroplating process, resulting in poor electroplating uniformity.

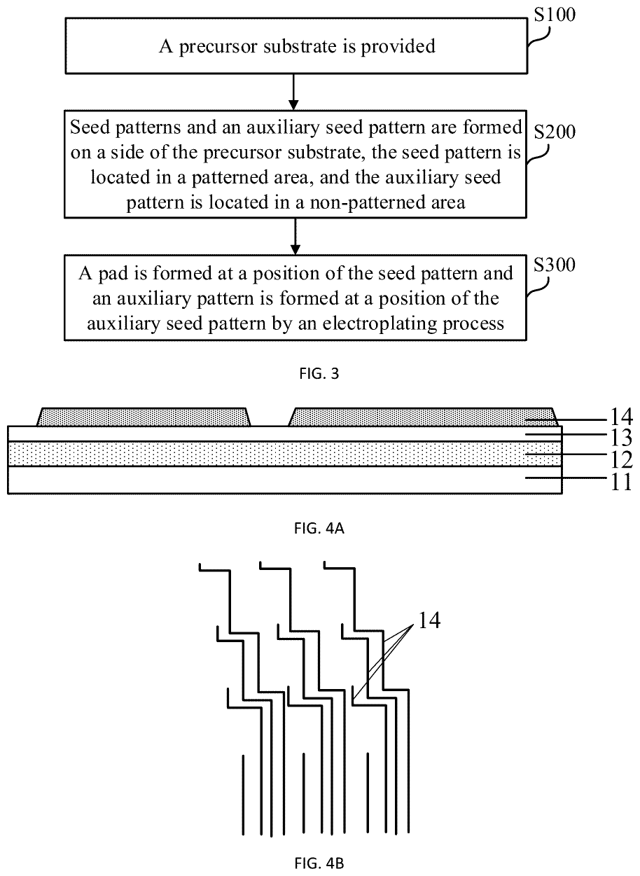

Referring to FIG. 3, embodiments of the present disclosure provide a manufacturing method for a circuit board, and the circuit board has a plurality of patterned areas and a non-patterned area located outside the patterned areas. In embodiments of the present disclosure, the circuit board may be a chip on film (COF), which has a bonding area (OLB Bonding) for bonding a display substrate, a bonding area (FOF Bonding) for bonding a flexible circuit board, and a bonding area (ILB Bonding) for bonding ICs. The patterns of different bonding areas may be different. The manufacturing method provided in embodiments of the present disclosure may also be applicable to other circuit boards formed by an electroplating process. The manufacturing method according to embodiments of the present disclosure includes following steps.

Step S100, a precursor substrate is provided.

The step S100 of providing a precursor substrate may include following steps.

Step S111, providing a base substrate 11. A material of the base substrate 11 may be a rigid substrate, and may be a glass substrate. The base substrate 11 may be removed after the circuit board is finally formed.

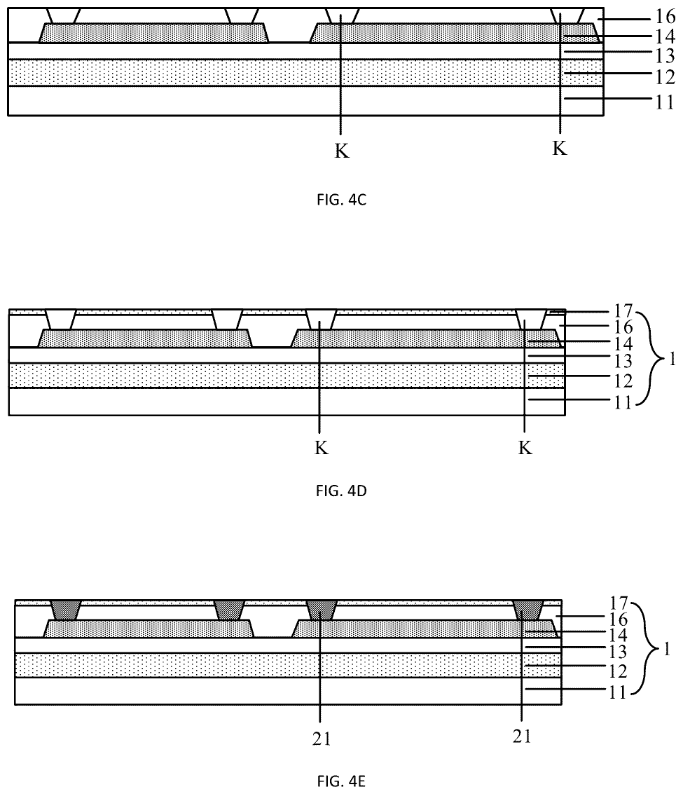

As shown in FIG. 4A, a flexible film 12 (polyimide, PI, may be used) may be coated or laminated on a side of the base substrate 11, and may have a thickness of 10 μm to 40 μm. A water-blocking inorganic film SiO2 or SiN, as a water-blocking layer 13, may be deposited on the flexible film 12, and may have a thickness of 100 nm to 500 nm. The flexible film 12 may be a single layer or a composite stacked-layer structure. When the flexible film 12 is a single layer, a material of the flexible film 12 may be polyimide (PI), polyethylene naphthalate, or polyethylene glycol terephthalate. When the flexible film 12 is a composite stacked-layer structure, the flexible film 12 may include a first organic layer, a blocking layer, and a second organic layer which are stacked in sequence. A material of the first organic layer may be polyimide, polyethylene naphthalate, or polyethylene glycol terephthalate. A material of the second organic layer may be polyimide, polyethylene naphthalate, or polyethylene glycol terephthalate.

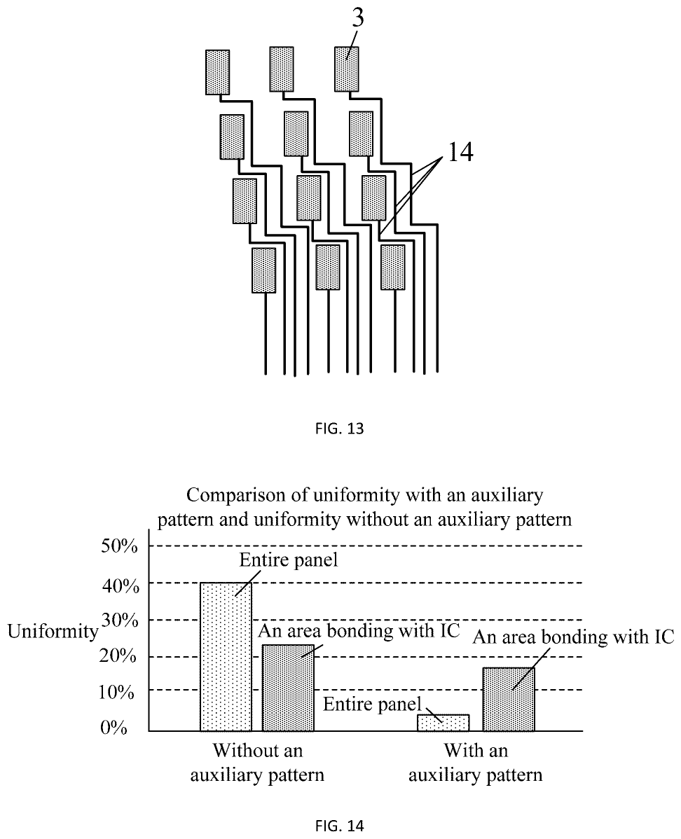

Step S112, a plurality of leads 14 on a side of the base substrate 11 are formed. The plurality of leads 14 may be formed on a side of the water-blocking layer 13 facing away from the flexible film 12. Forming the plurality of leads 14 may include: first depositing a layer of metal thin film, where the metal thin film may be made of Mo, Al, or stacked metal of Ti/Al/Ti, and the thickness can be 500 nm to 1000 nm by taking the metal of Ti/Al/Ti for illustration; and performing patterning. In order to achieve a smaller size (pitch), the etching process can be dry etching. The cross-sectional view is shown in FIG. 4A, the schematic diagram of the leads 14 for bonding pads 3 may be shown in FIG. 4B, and the schematic diagram of the top view of the leads 14 and the subsequently formed pads 3 may be shown in FIG. 13. Due to the accuracy limitation of the bonding device, the size of the pad 3 needs to be greater than 20 μm, and then the line width (pitch) of the lead 14 in the densest area of the wiring between the pads 3 needs to be less than 4 μm.

Step S113, a planarization layer 16 is formed on a side of the lead 14 facing away from the base substrate 11, as shown in FIG. 4C, and the planarization layer 16 has a via hole K exposing a portion of the lead 14. An organic insulating layer as the planarization layer 16 is coated on a side of the lead 14 facing away from the base substrate 11, the organic insulating layer may be made of resin and have a thickness of 2 μm to 5 am. A transfer via hole K is provided at a position where the pad 3 is located. The quantity of the transfer via holes K provided on the pad 3 may be one or more, and the schematic diagram takes one as an example.

An inorganic insulating layer of SiN or SiO stacked-layer, as an insulating layer 17, may also be deposited on a side of the planarization layer 16 facing away from the lead 14, as shown in FIG. 4D, and has the thickness of 100 nm to 500 nm. A transfer via hole may be provided at the position of the pad 3.

As shown in FIG. 4D, the formed precursor substrate may include a base substrate 11, leads 14 on a side of the base substrate 11, and a planarization layer 16 on a side of the leads 14 facing away from the base substrate 11. A flexible film 12 may also be provided between the base substrate 11 and the leads 14, a water-blocking layer 13 may also be provided between the flexible film 12 and the leads 14, and an insulating layer 17 may also be provided on a side of the planarization layer 16 facing away from the leads 14.

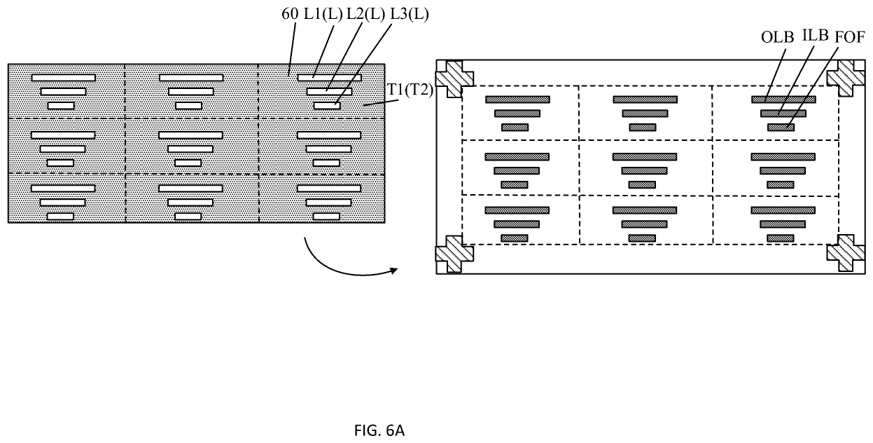

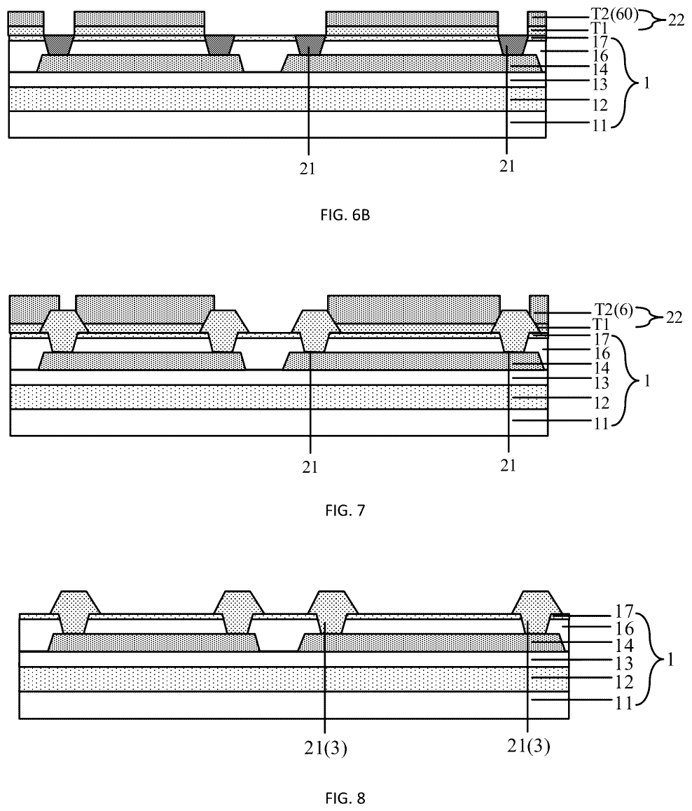

Step S200, seed patterns and an auxiliary seed pattern are formed on a side of the precursor substrate, where the seed pattern is located in a patterned area, the auxiliary seed pattern is located in a non-patterned area, and the seed pattern and the auxiliary seed pattern are separated from each other. As shown in FIG. 6B, the seed pattern 21 and the auxiliary seed pattern 60 may be separated by the first flexible substrate T1; or, as shown in FIG. 11, the seed pattern 21 and the auxiliary seed pattern 60 may be separated by a gap.

In the step S200, the seed patterns and the auxiliary seed pattern may be formed on the side of the precursor substrate by a variety of methods. In a possible implementation, the step S200 may include following steps.

Step S211, a plurality of seed patterns 21 are formed in patterned areas of the precursor substrate, as shown in FIG. 4E. After forming the precursor substrate, the seed patterns 21 may be formed at via holes K of the precursor substrate.

Step S212, an auxiliary film having an auxiliary seed pattern and a hollowed area are formed, where the auxiliary seed pattern includes: a first flexible substrate, and a first auxiliary seed film layer on a side of the first flexible substrate. The step S212 of forming the auxiliary film having the auxiliary seed pattern and the hollowed area may include following steps.

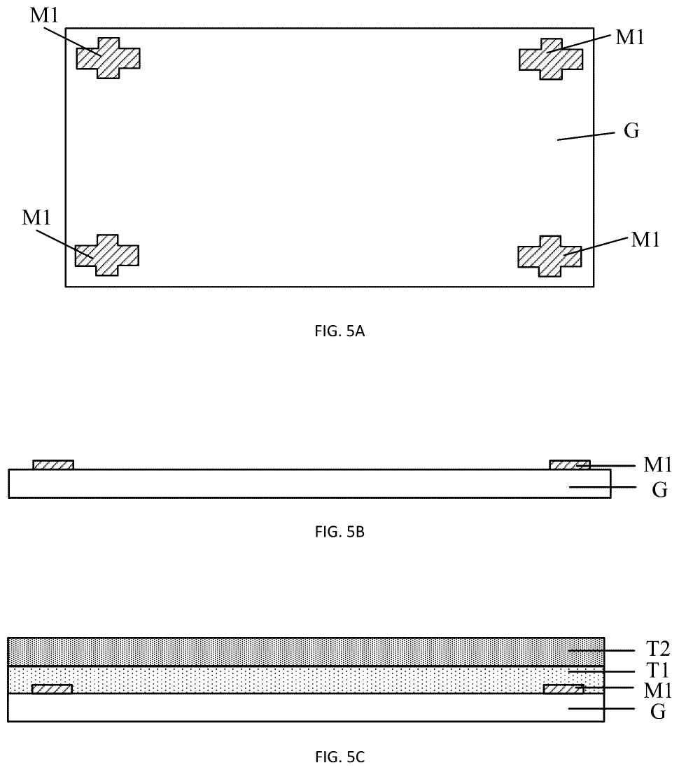

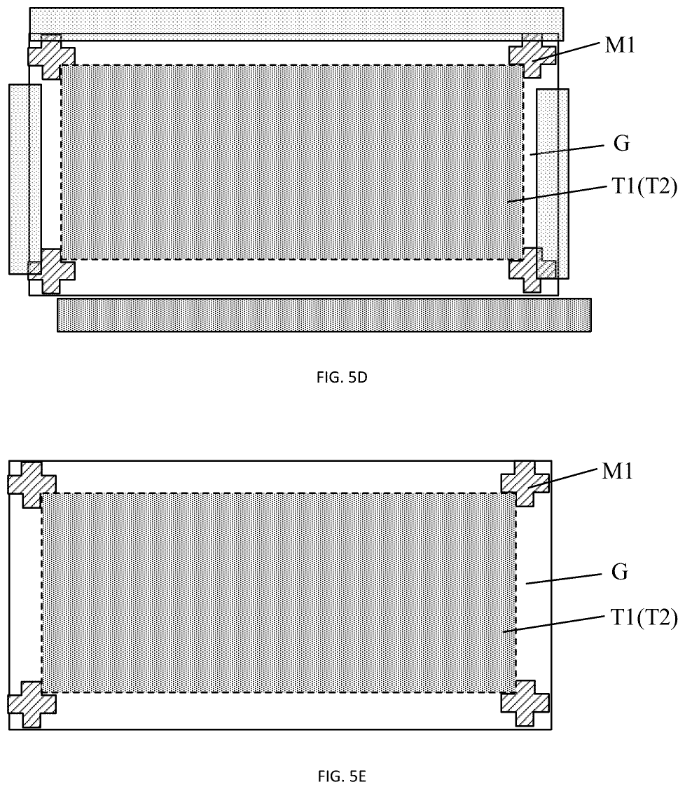

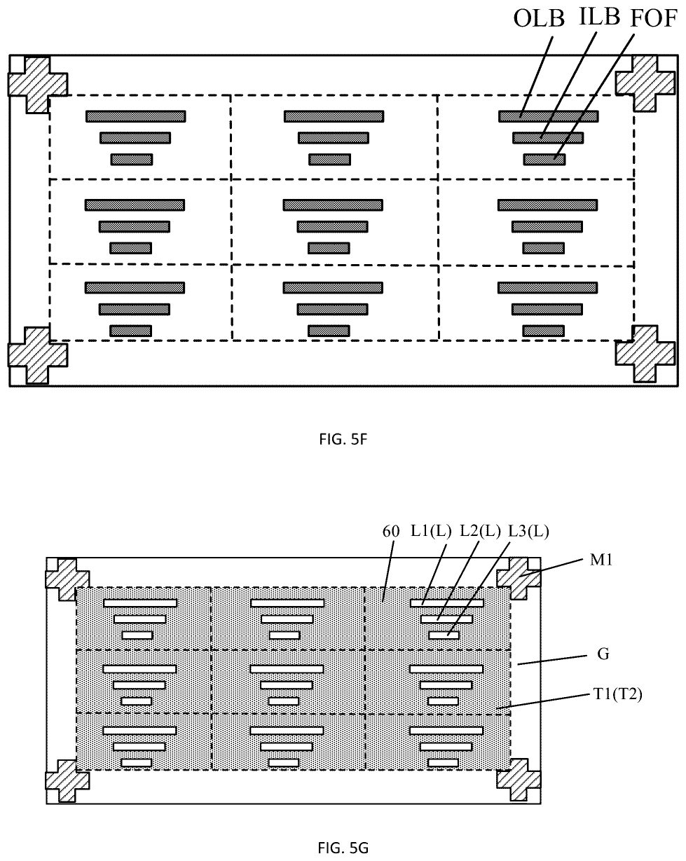

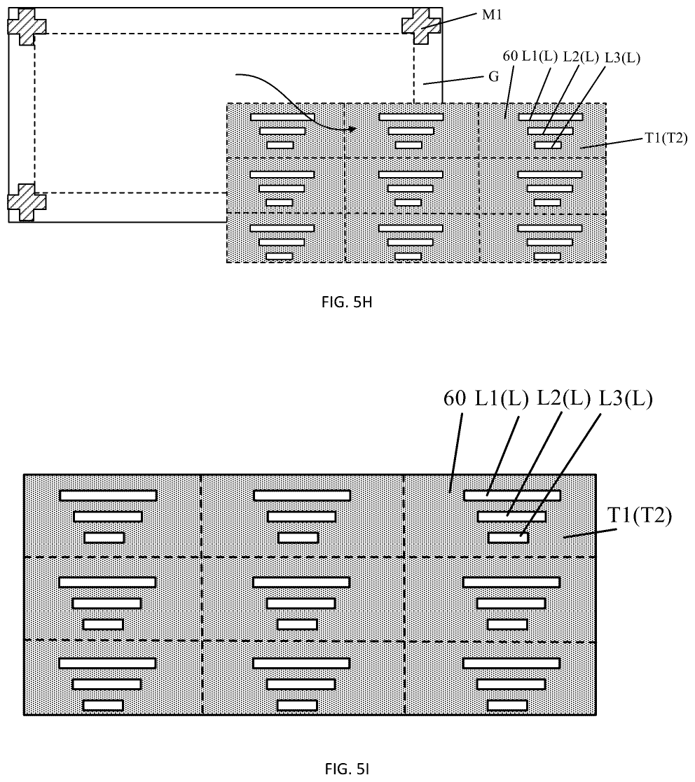

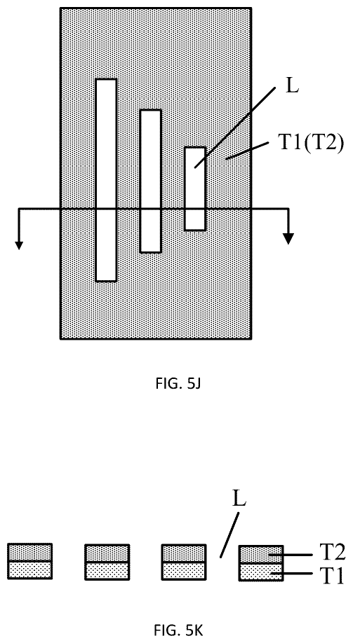

Step a, a rigid substrate is provided. The rigid substrate may be a glass substrate. As shown in FIGS. 5A and 5B, first alignment marks M1 may be made on the rigid substrate G. A layer of metal Mo with a thickness of 2000 Å to 2500 Å (e.g., 2200 Å) may be first deposited on the rigid substrate on the entire surface by using a sputter device, and then a photoresist coating process is performed by using a photolithography device. After that, a dry-etching process is used to retain only the first alignment marks M1 around the periphery, as shown in a planar schematic diagram and a cross-sectional schematic diagram in FIG. 5A and FIG. 5B.

Step b, referring to FIG. 5C, the first flexible substrate T1 and the first auxiliary seed film layer T2 are formed sequentially on a side of the rigid substrate G. By using a laminator, the entire TPF film (as the first flexible substrate T1) can be accurately and completely adhered to the rigid substrate G which is marked with the first alignment marks M1, and then a layer of Cu (as the first auxiliary seed film layer T2) with a thickness of 3000 Å is deposited on the TPF film (the first flexible substrate T1) by using a sputter device, as shown in FIG. 5C.

Step c, the first flexible substrate T1 and the first auxiliary seed film layer T2 are cut to remove an area without the auxiliary seed patterns, to form a hollowed area.

Laser cutting can be first used to accurately align the inner side of the first alignment marks M1 for laser cutting, to cut and peel off the TPF film (the first flexible substrate T1) and the first auxiliary seed film layer T2 on the inner sides of the first alignment marks M1, and a specific schematic diagram is shown in FIG. 5D. The laser cutting is used to cut and peel off a portion of the TPF film (the first flexible substrate T1) and the substrate of the first auxiliary seed film layer T2, as shown in FIG. 5E. Secondly, according to a second alignment mark (not shown in the figure) of the motherboard with a plurality of precursor substrates and a third alignment mark (not shown in the figure) on a single precursor substrate (e.g., COF) as well as distances of ILB, OLB, and FOF from a fourth alignment mark (not shown in the figure) in the single COF (the schematic diagram of distribution of the precursor substrates on the entire motherboard is shown in FIG. 5F), accurate cutting of the TPF film (the first flexible substrate T1) and the first auxiliary seed film layer T2 is realized to form the hollowed area L (the hollowed area L may include a first hollowed area L1 corresponding to the OLB bonding area on the precursor substrate in FIG. 5F, a second hollowed area L2 corresponding to the ILB bonding area, and a third hollowed area L3 corresponding to the FOF bonding area), and the remaining patterns are used as auxiliary seed patterns 60. The specific upper substrate after performing laser cutting is shown in FIG. 5G.

Step d, the rigid substrate is removed. The TPF film (the first flexible substrate T1) and the first auxiliary seed film layer T2 are removed from the rigid substrate G, as shown in FIG. 5H. A plan view of an auxiliary film made is as shown in FIG. 5I. A plan view of a single COF is shown in FIG. 5J, and a cross-sectional view at the position indicated by the arrow in FIG. 5J is as shown in FIG. 5K.

Step S213, a side of the auxiliary film having the first flexible substrate T1 is attached to a side of the precursor substrate having the seed pattern 21, as shown in FIG. 6B. A patterned area of the precursor substrate (e.g., an OLB, an ILB, or a FOF in FIG. 6A) is attached to a hollowed area L of the auxiliary film. The side of the auxiliary film having the first flexible substrate may be attached to the side of the precursor substrate having the seed pattern by the roller rolling. The precursor substrate 1 formed with the seed pattern 21 and the auxiliary film 22 are accurately and closely attached by rolling of two laminating rollers, as shown in FIG. 6A, and a cross-sectional view of the precursor substrate after adding the auxiliary seed pattern 60 is shown in FIG. 6B.

Step S300, a pad 3 is formed at a position of the seed pattern 21 and an auxiliary pattern 6 is formed at a position of the auxiliary seed pattern 60 by an electroplating process, as shown in FIG. 7.

After step S300, i.e., after forming the pad 3 at the position of the seed pattern 21 and the auxiliary pattern 6 at the position of the auxiliary seed pattern 60 by the electroplating process, the manufacturing method further includes: removing the auxiliary film 22, as shown in FIG. 8.

After removing the auxiliary film, the manufacturing method further includes following steps.

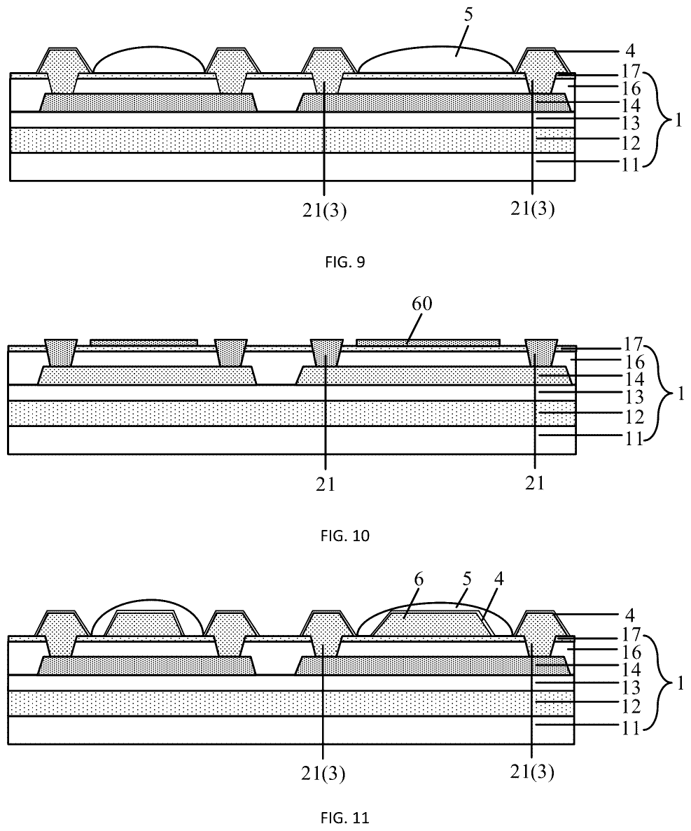

A protective layer 4 is formed on a surface of the pads 3, as shown in FIG. 9. A tinning process is performed to form the protective layer 4 to achieve an anti-oxidation effect on the pads 3.

A solder resist layer 5 is formed in a non-patterned area, as shown in FIG. 9. The solder resist layer 5 (e.g., green oil) is coated in the non-patterned area (e.g., area without the ILB, OLB, and FOF), and has a thickness of 10 μm to 20 μm. In an embodiment of the present disclosure, the auxiliary pattern 6 may not be retained in the final COF.

In another possible implementation, the step S200 of forming the seed patterns and the auxiliary seed pattern on the side of the precursor substrate includes following steps.

Step S221, a second seed film layer 61 is formed on the precursor substrate by a sputtering process, as shown in FIG. 10. A Cu seed layer is deposited on the precursor substrate by using a sputter device, and has a thickness of 2500 Å to 3500 Å (e.g., 3000 Å). A process of forming the precursor substrate in embodiments of the present disclosure is the same as the process of forming the precursor substrate as described above, and is not described herein.

Step S222, a plurality of seed patterns 21 are formed in patterned areas, and an auxiliary seed pattern 60 is formed in the non-patterned area, by performing a patterning process on the second seed film layer 61, where a gap is provided between the auxiliary seed pattern 60 and the seed pattern 21, as shown in FIG. 10. The patterning process may be performed by using a photolithography process.

After forming the pad at the position of the seed pattern and the auxiliary pattern at the position of the auxiliary seed pattern by an electroplating process, the manufacturing method further includes following steps.

A protective layer 4 is formed on surfaces of the pad 3 and the auxiliary pattern 6, as shown in FIG. 11. A tinning process is performed to form the protective layer 4 to realize the anti-oxidation effect on the pads 3. The material of the protective layer 4 may be tin (Sn) metal and the like. In some embodiments, a chemical electroplating process may be used to form the protective layer 4, and the thickness of the protective layer 4 is greater than or equal to 0.5 μm and less than or equal to 2 μm, for example 0.5 μm, 1 am, 1.5 μm, 2 μm, etc. Furthermore, indium tin oxide (ITO) may also cover the surface of the pads 3 to prevent the pads 3 from being oxidized.

A solder resist layer 5 is formed in the area where the auxiliary pattern 6 is located. The solder resist layer 5 is formed at the position of the auxiliary pattern 6, as shown in FIG. 11. The solder resist layer 5 (e.g., green oil) may be coated in the non-patterned area (e.g., the area without the ILB, OLB, and FOF). The thickness of the solder resist layer 5 may be greater than or equal to 10 μm and less than or equal to 20 μm. Optionally, the thickness of the solder resist layer 5 is 10 μm, 15 μm, 20 am or the like. In embodiments of the present disclosure, the auxiliary pattern 6 may be retained on the final COF.

In embodiments of the present disclosure, the electroplating uniformity without adding an auxiliary pattern and with an auxiliary pattern added is shown in FIG. 14, and the following can be obtained.
1. When adding the auxiliary pattern, the electroplating uniformity of the motherboard including multiple COFs can be effectively improved (the uniformity therein can be understood as the uniformity between the same patterns, the smaller the uniformity, the smaller the thickness difference between the same patterns, and the more the requirements of the latter bonding process are met). Compared with the previous electroplating uniformity of 40% for the motherboard including multiple COFs without an auxiliary pattern, embodiments of the present disclosure add an auxiliary pattern and can reduce the electroplating uniformity of the entire motherboard to 4%.
2. Adding the auxiliary pattern can also improve the uniformity of patterns of the COFs in the bonding area. Compared with the previous electroplating uniformity of 23% in the bonding area without an auxiliary pattern, embodiments of the present disclosure add an auxiliary pattern and can reduce the electroplating uniformity of the entire motherboard to 17%, which has a better improvement effect of the electroplating uniformity.

It should be noted that in embodiments of the present disclosure, the electroplating uniformity includes the electroplating uniformity of the motherboard including multiple COFs and the uniformity of the bonding area (e.g., the place of bonding the ILB). The uniformity of the entire motherboard is to test the electroplating thickness of Cu at the fixed position of each single COF on the motherboard and calculate the uniformity of the electroplated Cu. The electroplating uniformity of the ILB is to calculate the uniformity of the electroplated Cu by selecting the thicknesses of electroplated Cu at different positions at the place of bonding the ILB in a single COF.

Embodiments of the present disclosure can replace the COF product structure and scheme in the related art. In the related art, the COF structure is electroplated by the additive process, the planarization layer (Resin) serves as a retaining wall, and the uniformity gets worse as the thickness of the electroplated Cu increases. The thickness uniformity of Cu at the COF pads is poor in the related art, so that, on one hand, it causes different resistance of different pads, and on the other hand, it causes a decrease in the product yield during bonding, affecting the final performance of the device.

The manufacturing method for the circuit board according to embodiments of the present disclosure can be applied to the manufacturing process of high-resolution COF device structures in the display field, and the patterned process of electroplating the thick Cu in the mini-light emitting diode (Mini-LED) and micro-light emitting diode (Micro-LED) technology.

Beneficial effects of embodiments of the present disclosure are as follows: by setting an auxiliary pattern in the non-patterned area of the circuit board, the uniformity of the distribution of the power lines is enhanced when electroplating the thick metal (e.g., the thick Cu larger than 8 μm) at the pads, improving and enhancing the thickness uniformity of the metal at the pads, and enhancing the product yield of the circuit board during bonding later.

Based on the same inventive concept, embodiments of the present disclosure further provide a circuit board, including:
a base substrate 11, having patterned areas and a non-patterned area located outside the patterned areas;
a plurality of pads 3, located on a side of the base substrate 11 and located in the patterned areas; and
an auxiliary pattern 6, where the auxiliary pattern 6 and the pads 3 are located on the same side of the base substrate 11, and the auxiliary pattern 6 is located in the non-patterned areas. The auxiliary pattern 6 may be an entire pattern that surrounds the patterned areas.

In a possible implementation, as shown in FIG. 11, a gap is provided between the auxiliary pattern 6 and the pad 3, which avoids other unwanted adverse effects of the auxiliary pattern 6 on the COF circuit board.

In a possible implementation, as shown in FIG. 11, the auxiliary pattern 6 and the pads 3 are on the same layer and have the same material. The material of the auxiliary pattern 6 and the pads 3 may be copper.

In a possible implementation, shown in FIG. 11, a surface of the auxiliary pattern 6 facing away from the base substrate 11 is on the same plane as a surface of the pad 3 facing away from the base substrate 11.

In a possible implementation, shown in FIG. 11, the circuit board further includes:
a plurality of leads 14, located between the base substrate 11 and the pads 3;
a planarization layer 16, located between the leads 14 and the pads 3, and having via holes exposing portions of the leads 14, where the leads 14 are electrically connected with the pads 3 in one-to-one correspondence through the via holes;
a protective layer 4, located on a side of the pad 3 facing away from the planarization layer 16 and covering the pads 3 and the auxiliary pattern 6; and
a solder resist layer 5, located on a side of the auxiliary pattern 6 facing away from the planarization layer 16 and covering the auxiliary pattern 6.

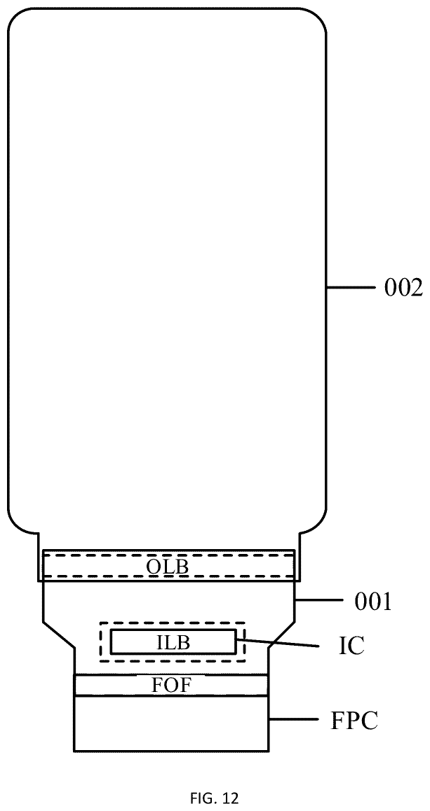

Based on the same inventive conception, embodiments of the present disclosure further provide a display apparatus, referring to FIG. 12, including: a display panel 002, a flexible circuit board FPC, a control chip IC, and a circuit board 001 obtained by the manufacturing method according to embodiments of the present disclosure, or, a circuit board 001 according to embodiments of the present disclosure. A plurality of patterned areas of the circuit board 001 include: a first patterned area OLB, a second patterned area FOF, and a third patterned area ILB.

The display panel includes a plurality of first pins, and the first pins of the display panel are bonded one-to-one with pads in the first patterned area OLB.

The flexible circuit board includes a plurality of second pins, and the second pins of the circuit board are bonded one-to-one with pads in the second patterned area FOF.

The control chip has a plurality of third pins, and the third pins of the control chip are bonded one-to-one with pads in the third patterned area ILB.

The beneficial effects of embodiments of the present disclosure are as follows: the uniformity of the distribution of the power lines is enhanced when electroplating the thick metal (e.g., the thick Cu larger than 8 μm) at the pads, by setting the auxiliary pattern in the non-patterned area of the circuit board, thus improving and enhancing the thickness uniformity of the metal at the pads, and enhancing the product yield of the circuit board during bonding later.

In some embodiments, the display apparatus according to embodiments of the present disclosure may be a liquid crystal display apparatus. The liquid crystal display apparatus includes a backlight module, and a liquid crystal display panel located on a light-emitting side of the backlight module. Herein, the liquid crystal display panel may be a twisted nematic (TN) liquid crystal display panel, an advanced dimension switch (ADS) liquid crystal display panel, a high-advanced dimension switch (HADS) liquid crystal display panel, an in-plane switch (IPS) liquid crystal display panel, or the like.

In some embodiments, the display apparatus according to embodiments of the present disclosure may be a 3D display apparatus, herein, the display apparatus may also include a liquid crystal grating disposed between the backlight module and the liquid crystal display panel, and the liquid crystal grating may be fixed together with the liquid crystal display panel by a bonding layer. Optionally, according to a current position of eyes of a viewer, the liquid crystal grating may be controlled to form alternately arranged light-transmitting areas and light-shading areas, so that the left eye of the viewer sees the left eye image displayed in the display panel through the light-transmitting areas of the liquid crystal grating, and the right eye sees the right eye image displayed in the display panel through the light-transmitting areas. By setting the liquid crystal grating on the light-entry side of the liquid crystal display panel, when the liquid crystal display panel includes touch electrodes, the liquid crystal grating does not shield the touch electrodes in the liquid crystal display panel, avoiding the problem of touch failure, so that the touch sensitivity and accuracy of the liquid crystal display panel can be improved.

In some embodiments, the display panel in the above display apparatus according to embodiments of the present disclosure may also be an electroluminescent display panel (organic light emitting diodes, OLED), or a quantum dot display panel (quantum dot light emitting diodes, QLED), which is not limited herein. The OLED display panel or QLED display panel includes a light-emitting device, and a pixel driving circuit electrically connected to the light-emitting device. The light-emitting device may include a cathode and an anode opposite to each other, and a light-emitting functional layer between the cathode and the anode. The pixel driving circuit may include a thin film transistor, a storage capacitor and the like. The pixel driving circuit may be realized in various different types, such as the 2TIC type (i.e., including two thin film transistors and one storage capacitor). The pixel driving circuit may further include more transistors and/or capacitors on the basis of the 2T1C type to have functions such as compensation, reset, light-emitting control, detection, and the like. Embodiments of the present disclosure do not limit the pixel driving circuit. For example, in some embodiments, the thin film transistor directly electrically connected to the light-emitting device may be a driver transistor (Td) or a light-emitting control transistor (EM), etc.

In some embodiments, the above display apparatus according to embodiments of the present disclosure may be: a cell phone, a tablet computer, a television, a monitor, a laptop computer, a digital photo frame, a navigator, a smartwatch, a fitness wristband, a personal digital assistant, and any other product or component having a display function. Optionally, the above display apparatus according to embodiments of the present disclosure includes, but is not limited to, components such as: a radio frequency unit, a network module, an audio output & input unit, a sensor, a display unit, a user input unit, an interface unit, and a control chip. Optionally, the control chip is a central processing unit, a digital signal processor, a system-on-chip (SoC), and the like. For example, the control chip may also include a memory, and may also include a power supply module and the like. The control chip realizes the power supply and the signal input and output functions through additionally provided wires, signal lines, and the like. For example, the control chip may also include a hardware circuit, computer executable codes, and the like. The hardware circuit may include conventional very large scale integration (VLSI) circuits or gate arrays as well as existing semiconductors, such as logic chips and transistors, or other discrete components. The hardware circuit may also include the field programmable gate array, the programmable array logic, the programmable logic device, and the like. In addition, those skilled in the art can understand that the above structure does not constitute a limitation of the above display apparatus according to embodiments of the present disclosure. In other words, the above display apparatus according to embodiments of the present disclosure may include more or fewer of the above components, or a combination of certain components, or a different arrangement of components.

Although embodiments of the present disclosure have been described, those skilled in the art may make additional changes and modifications to these embodiments once the basic inventive concepts are known. Therefore, the appended claims are intended to be construed to include embodiments as well as all changes and modifications that fall within the scope of the present disclosure.

Obviously, those skilled in the art may make various modifications and variations to embodiments of the present disclosure without departing from the spirit and scope of embodiments of the present disclosure. Thus, if these modifications and variations of embodiments of the present disclosure fall within the scope of the claims of the present disclosure and their technical equivalents, the present disclosure is intended to encompass these modifications and variations as well.

What is claimed is:

1. A manufacturing method for a circuit board, wherein the circuit board has a plurality of patterned areas, and a non-patterned area outside the patterned areas, wherein the manufacturing method comprises:
providing a precursor substrate;
forming seed patterns and an auxiliary seed pattern on a side of the precursor substrate, wherein the seed patterns are located in the patterned areas, the auxiliary seed pattern is located in the non-patterned area, and the seed pattern and the auxiliary seed pattern are separated from each other; and
forming a pad at a position of the seed pattern and an auxiliary pattern at a position of the auxiliary seed pattern by an electroplating process.

2. The manufacturing method according to claim 1, wherein the forming the seed patterns and the auxiliary seed pattern on the side of the precursor substrate, comprises:
forming a plurality of the seed patterns in the patterned areas of the precursor substrate;
forming an auxiliary film having the auxiliary seed pattern and a hollowed area, wherein the auxiliary seed pattern comprises: a first flexible substrate, and a first auxiliary seed film layer on a side of the first flexible substrate; and
attaching a side of the auxiliary film having the first flexible substrate to a side of the precursor substrate having the seed pattern, wherein the patterned area of the precursor substrate is attached to the hollowed area of the auxiliary film.

3. The manufacturing method according to claim 2, wherein the forming the auxiliary film having the auxiliary seed pattern and the hollowed area, comprises:
providing a rigid substrate;
forming the first flexible substrate and the first auxiliary seed film layer sequentially on a side of the rigid substrate;
cutting the first flexible substrate and the first auxiliary seed film layer to remove an area without the auxiliary seed pattern to form the hollowed area; and
removing the rigid substrate.

4. The manufacturing method according to claim 3, wherein the attaching the side of the auxiliary film having the first flexible substrate to the side of the precursor substrate having the seed pattern, comprises:
attaching the side of the auxiliary film having the first flexible substrate to the side of the precursor substrate having the seed pattern by a roller rolling.

5. The manufacturing method according to claim 2, wherein, after forming the pad at the position of the seed pattern and the auxiliary pattern at the position of the auxiliary seed pattern by the electroplating process, the manufacturing method further comprises:
removing the auxiliary film.

6. The manufacturing method according to claim 5, wherein, after removing the auxiliary film, the manufacturing method further comprises:
forming a protective layer on a surface of the pad; and
forming a solder resist layer in the non-patterned area.

7. The manufacturing method according to claim 1, wherein the forming the seed patterns and the auxiliary seed pattern on the side of the precursor substrate, comprises:
forming a second seed film layer on the precursor substrate by a sputtering process; and
forming a plurality of the seed patterns in the patterned areas, and forming the auxiliary seed pattern in the non-patterned area, by performing a patterning process on the second seed film layer, wherein a gap is provided between the auxiliary seed pattern and the seed pattern.

8. The manufacturing method according to claim 7, wherein, after forming the pad at the position of the seed pattern and the auxiliary pattern at the position of the auxiliary seed pattern by the electroplating process, the manufacturing method further comprises:
forming a protective layer on surfaces of the pad and the auxiliary pattern; and
forming a solder resist layer in an area where the auxiliary pattern is located.

9. The manufacturing method according to claim 1, wherein the providing the precursor substrate, comprises:
providing a base substrate;
forming a plurality of leads on a side of the base substrate; and
forming a planarization layer on a side of the leads facing away from the base substrate, wherein the planarization layer has via holes exposing portions of the leads.

10. A circuit board, comprising:
a base substrate, wherein the base substrate has patterned areas and a non-patterned area outside the patterned areas;
a plurality of pads, located on a side of the base substrate and located in the patterned areas; and
an auxiliary pattern, wherein the auxiliary pattern and the pads are on a same side of the base substrate, and the auxiliary pattern is in the non-patterned area.

11. The circuit board according to claim 10, wherein a gap is provided between the auxiliary pattern and the pad.

12. The circuit board according to claim 10, wherein the auxiliary pattern and the pads are on a same layer and have a same material.

13. The circuit board according to claim 10, wherein a surface of the auxiliary pattern facing away from the base substrate is on a same plane as a surface of the pad facing away from the base substrate.

14. The circuit board according to claim 10, wherein the circuit board further comprises:
a plurality of leads between the base substrate and the pads;
a planarization layer, located between the plurality of leads and the pads, and having via holes exposing portions of the plurality of leads, wherein the plurality of leads are electrically connected with the pads in one-to-one correspondence through the via holes;
a protective layer, located on a side of the pad facing away from the planarization layer and covering the pad and the auxiliary pattern; and
a solder resist layer, located on a side of the auxiliary pattern facing away from the planarization layer and covering the auxiliary pattern.

15. A display apparatus, comprising:
a display panel;
a flexible circuit board;
a control chip; and
a circuit board obtained by the manufacturing method according to claim 1;
wherein the plurality of patterned areas of the circuit board comprise: a first patterned area, a second patterned area, and a third patterned area;
the display panel comprises a plurality of first pins, and the plurality of first pins of the display panel are bonded one-to-one with pads in the first patterned area;
the flexible circuit board comprises a plurality of second pins, and the plurality of second pins of the flexible circuit board are bonded one-to-one with pads in the second patterned area; and
the control chip comprises a plurality of third pins, and the plurality of third pins of the control chip are bonded one-to-one with pads in the third patterned area.

16. A display apparatus, comprising:
a display panel;
a flexible circuit board;
a control chip; and
the circuit board according to claim 10;
wherein the plurality of patterned areas of the circuit board comprise: a first patterned area, a second patterned area, and a third patterned area;
the display panel comprises a plurality of first pins, and the plurality of first pins of the display panel are bonded one-to-one with pads in the first patterned area;
the flexible circuit board comprises a plurality of second pins, and the plurality of second pins of the flexible circuit board are bonded one-to-one with pads in the second patterned area; and
the control chip comprises a plurality of third pins, and the plurality of third pins of the control chip are bonded one-to-one with pads in the third patterned area.
